(19) United States
(12) Patent Application Publication
(10) Pub. No.: US 2026/0029718 A1
(43) Pub. Date: Jan. 29, 2026

(54) SUBSTRATE PROCESSING APPARATUS AND SUBSTRATE PROCESSING METHOD

(71) Applicant: SEMES CO., LTD., Cheonan-si (KR)

(72) Inventors: Gyeong Won SONG, Cheonan-si (KR); Gu Won SEON, Seoul (KR); Dae Sung KIM, Cheonan-si (KR)

(73) Assignee: SEMES CO., LTD., Cheonan-si (KR)

(21) Appl. No.: 19/266,322

(22) Filed: Jul. 11, 2025

(30) Foreign Application Priority Data
Jul. 24, 2024 (KR) 10-2024-0097903

(51) Int. Cl. G03F 7/16

(52) U.S. Cl. CPC G03F 7/16

(57) ABSTRACT

Disclosed is a substrate processing apparatus including a liquid supply unit. The liquid supply unit includes: a bottle; a supply pipe for providing a path for a liquid in the bottle to flow to a liquid treating chamber; a trap tank installed in the supply pipe; a pump installed downstream of the trap tank in the supply pipe; and a gas supply unit for supplying gas. The gas supply unit includes: a main pipe; a branch pipe branched from the main pipe and connected to a storage space of the bottle; and a regulator installed upstream from a branch point where the branch pipe is branched from the main pipe in the main pipe to reduce pressure of gas supplied from the gas supply source.

### CROSS-REFERENCE TO RELATED APPLICATIONS

This application claims priority to and the benefit of Korean Patent Application No. 10-2024-0097903 filed in the Korean Intellectual Property Office on Jul. 24, 2024, the entire contents of which are incorporated herein by reference.

### TECHNICAL FIELD

The present invention relates to a substrate processing apparatus in a device for liquid treating a substrate and a liquid supply unit used therein.

### BACKGROUND ART

In order to manufacture a semiconductor device, various processes, such as cleaning, deposition, photography, etching, and ion implantation, are performed. Among the processes, the photography process includes a coating process of forming a film by applying a photoresist, such as a photoresist, on a surface of the substrate, an exposure process that transfers a circuit pattern to a film formed on the substrate, and a developing process that selectively removes a film formed on the substrate in a region on which the exposure process has been performed or a region opposite to the region.

Typically, a device that performs an coating process supplies photoresist from a nozzle onto a rotating substrate to form a liquid film on the substrate. FIG. 1 schematically illustrates a structure of a general liquid supply unit that supplies photoresist to a nozzle. Referring to FIG. 1, a liquid supply unit 9000 stores photoresist in a bottle 9100 in a trap tank 9500, and then supplies the photoresist in the trap tank 9500 to a nozzle 9800 via a pump 9700.

The bottle 9100 is connected to a gas supply pipe 9310, and the gas supply unit 9300 supplies high pressure gas into the bottle 9100 via the gas supply pipe 9310. Typically, the gas is supplied such that the pressure within the bottle 9100 is raised to tens of kPa in order to cause the photoresist within the bottle 9100 to be transferred to the trap tank 9500 by the gas pressure.

However, the high gas pressure increases the dissolved amount of gas in the photoresist stored in the bottle 9100, and a large amount of bubbles are generated in the photoresist as the photoresist flows along the supply pipes 9910 and 9930 or is applied onto the substrate W. As a result, less than the set amount of photoresist is applied to the substrate W, affecting the thickness of the applied liquid film and causing process defects.

### SUMMARY OF THE INVENTION

The present invention has been made in an effort to provide a substrate processing apparatus and a substrate processing method that are capable of improving the processing efficiency of a substrate.

The present invention has also been made in an effort to provide a substrate processing apparatus and a substrate processing method that are capable of preventing a large amount of bubbles from being generated in a liquid supplied to a substrate.

Effects of the present disclosure are not limited to those described above and effects not stated above will be clearly understood to those skilled in the art from the specification and the accompanying drawings.

An exemplary embodiment of the present invention, an apparatus for processing a substrate, the apparatus may further include; a liquid treating chamber for processing a substrate; and a liquid supply unit for supplying a liquid to the substrate disposed in the liquid treating chamber, wherein the liquid supply unit includes: a bottle in which a storage space for storing a liquid is formed; a supply pipe for providing a path through which the liquid in the bottle flows to the liquid treating chamber; a trap tank installed in the supply pipe and having an interior space where the liquid delivered from the bottle is stored; a pump installed downstream of the trap tank in the supply pipe and providing flow pressure to the liquid flowing in the supply pipe; and a gas supply unit for supplying gas to the storage space, and the gas supply unit includes: a main pipe for receiving the gas from the gas supply source and exhausting the received gas to the outside; a branch pipe branched from the main pipe and connected to the storage space of the bottle; and a regulator installed upstream from a branch point where the branch pipe is branched from the main pipe in the main pipe to reduce pressure of the gas supplied from the gas supply source.

According to the exemplary embodiment of the present invention, the gas supply unit may further includes a resistor that is installed in the main pipe downstream from the regulator to reduce the pressure of the gas.

According to the exemplary embodiment of the present invention, the resistor may be installed between the regulator and the branch point.

According to the exemplary embodiment of the present invention, the resistor may be a flow control valve.

According to the exemplary embodiment of the present invention, the resistor may be an orifice.

According to the exemplary embodiment of the present invention, the gas supply unit may further includes: a first resistor installed in the main pipe downstream from the regulator and reducing the pressure of the gas; and a second resistor installed in the main pipe downstream from the first resistor to reduce an exhaust amount of the gas.

According to the exemplary embodiment of the present invention, the gas may be inert gas.

According to the exemplary embodiment of the present invention, the branch point may be a position where a gauge pressure in the storage space is maintained at several Pa.

According to the exemplary embodiment of the present invention, the liquid supply unit may further includes a liquid delivering unit that delivers a liquid from the bottle to the trap tank.

According to the exemplary embodiment of the present invention, the liquid delivering unit may form negative pressure in the interior space of the trap tank to deliver the liquid from the bottle to the trap tank.

According to the exemplary embodiment of the present invention, the apparatus may further include a second liquid treating chamber for processing a second substrate; and a second liquid supply unit for supplying a second liquid to the second substrate disposed in the second liquid treating chamber, wherein the second liquid supply unit includes: a second bottle in which a second storage space for storing the second liquid is formed; a second supply pipe for providing a path through which the second liquid in the second bottle flows to the second liquid treating chamber; a second trap tank installed in the second supply pipe and having an interior space in which the second liquid delivered from the second bottle is stored; a second liquid delivering unit for delivering a liquid from the second bottle to the second trap tank; a second pump installed downstream of the second trap tank in the second supply pipe and providing flow pressure to the second liquid flowing in the second supply pipe; and a second branch pipe for receiving gas from the gas supply source, and the second branch pipe is branched from the main pipe downstream from the branch pipe and may connected to the storage space of the bottle.

An exemplary embodiment of the present invention, a method of processing a substrate, the method comprising: delivering a liquid in a storage space of a bottle to a trap tank and supplying the liquid in the trap tank to process the substrate, wherein gas is supplied from a gas supply source to the storage space, and the supply of the gas is accomplished through a branch pipe branched from a main pipe that depressurizes the gas supplied from the gas supply source through a regulator and then exhausts the depressurized gas to the atmosphere.

According to the exemplary embodiment of the present invention, the liquid may be a photoresist liquid.

According to the exemplary embodiment of the present invention, the gas may be supplied to the storage space so that a gauge pressure in the storage space is maintained at several Pa.

According to the exemplary embodiment of the present invention, the gas may be supplied to the storage space by reducing the pressure in the storage space that occurs when a liquid is delivered from the bottle to the trap tank.

According to the exemplary embodiment of the present invention, the pressure in the storage space may be the same before and after the liquid is delivered from the bottle to the trap tank.

According to the exemplary embodiment of the present invention, the gas is supplied from the gas supply source to a second bottle having a second storage space through a second branch pipe branched from the main pipe, and a second liquid in the second storage space of the second bottle is delivered to a second trap tank, and the second liquid in the second trap tank is supplied to the second substrate may process a second substrate.

An exemplary embodiment of the present invention, an apparatus for processing a substrate, the apparatus comprising: a liquid treating chamber for processing a substrate; and a liquid supply unit for supplying a liquid to the substrate disposed in the liquid treating chamber, wherein the liquid supply unit includes: a bottle in which a storage space for storing a liquid is formed; a supply pipe for providing a path through which the liquid in the bottle flows to the liquid treating chamber; a trap tank installed in the supply pipe and having an interior space where the liquid delivered from the bottle is stored; a liquid delivering unit for delivering a liquid from the bottle to the trap tank; a pump installed downstream of the trap tank in the supply pipe and providing flow pressure to the fluid flowing in the supply pipe; and a gas supply unit for supplying inert gas to the storage space, and the gas supply unit includes: a main pipe for receiving the inert gas from the gas supply source and exhausting the received inert gas to the outside; a branch pipe branched from the main pipe and connected to the storage space of the bottle; a regulator installed upstream from a branch point where the branch pipe is branched from the main pipe in the main pipe to reduce pressure of the inert gas supplied from the gas supply source; a first flow control valve installed in the main pipe between the regulator and the branch point to reduce the pressure of the inert gas; and a second flow control valve may installed in the main pipe downstream from the branch point to reduce the exhaust amount of the inert gas.

According to the exemplary embodiment of the present invention, the branch point may be a position where a gauge pressure in the storage space is maintained at several Pa.

According to the exemplary embodiment of the present invention, the apparatus may further include a second liquid treating chamber for processing a second substrate; and a second liquid supply unit for supplying a second liquid to the second substrate disposed in the second liquid treating chamber, wherein the second liquid supply unit includes: a second bottle in which a second storage space for storing the second liquid is formed; a second supply pipe for providing a path through which the second liquid in the second bottle flows to the second liquid treating chamber; a second trap tank installed in the second supply pipe and having an interior space in which the second liquid delivered from the second bottle is stored; a second liquid delivering unit for delivering the second liquid from the second bottle to the second trap tank; a second pump installed downstream of the second trap tank in the second supply pipe and providing flow pressure to the second liquid flowing in the second supply pipe; and a second branch pipe for receiving gas from the gas supply source, and the second branch pipe is installed in the main pipe between the branch point and the second flow control valve and may connected to the second storage space of the second bottle.

According to the exemplary embodiment of the present invention, it is possible to improve substrate processing efficiency.

According to the exemplary embodiment of the present invention, it is possible to prevent a large amount of bubbles from being generated in the liquid supplied to the substrate.

According to the exemplary embodiment of the present invention, the gauge pressure of the storage space in the bottle may be maintained at several Pa.

Effects of the present disclosure are not limited to those described above and effects not stated above will be clearly understood to those skilled in the art from the specification and the accompanying drawings.

### BRIEF DESCRIPTION OF THE DRAWINGS

FIG. 1 is a diagram illustrating an example of a general liquid supply unit for supplying a liquid to a nozzle.

FIG. 2 is a diagram schematically illustrating a substrate processing apparatus according to an exemplary embodiment of the present invention.

FIG. 3 is a diagram schematically illustrating one example of the liquid treating chamber of FIG. 2.

FIG. 4 is a diagram schematically illustrating one example of a liquid delivering unit of FIG. 2.

FIG. 5 is a diagram schematically illustrating one example of a gas supply unit of FIG. 2.

FIGS. 6 and 7 are diagrams schematically illustrating one exemplary embodiment of a process in which the liquid delivering unit operates to transfer a liquid in the substrate processing apparatus of FIG. 2.

FIG. 8 is a diagram schematically illustrating one exemplary embodiment of the substrate processing apparatus of FIG. 2 in a state where a pump does not operate after a valve installed in a suction pipe has been closed.

FIG. 9 is a diagram schematically illustrating one exemplary embodiment of a process of liquid transfer in the substrate processing apparatus of FIG. 2 in a state where the pump operates after the valve installed in the suction pipe has been closed.

FIG. 10 is a diagram schematically illustrating another exemplary embodiment of the substrate processing apparatus of FIG. 2.

FIG. 11 is a diagram schematically illustrating another exemplary embodiment of the liquid delivering unit of FIG. 4.

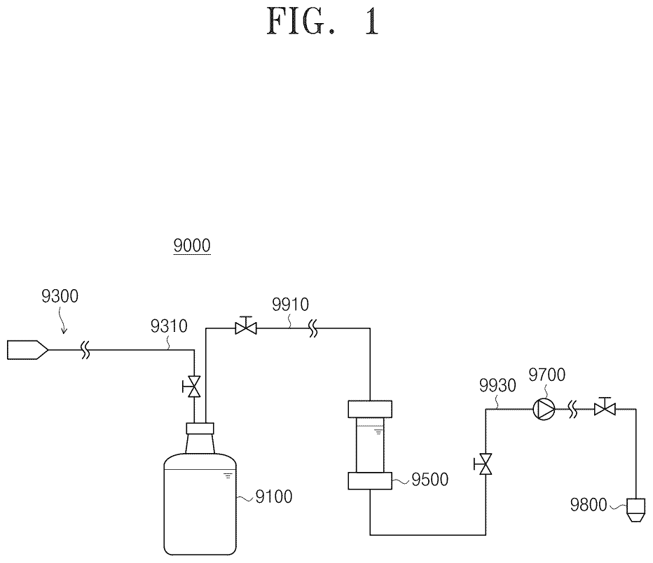

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

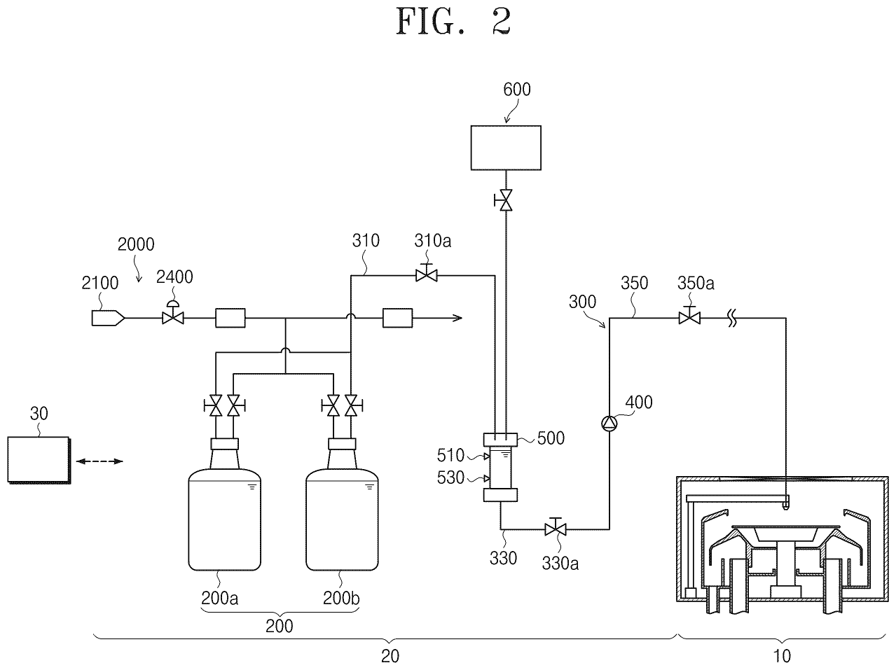

Hereinafter, an exemplary embodiment of the present invention will be described with reference to FIGS. 2 to 11.

In the following exemplary embodiment, a case where a substrate processing apparatus is an apparatus for performing a coating process of applying a photoresist on a substrate will be described as an example. However, unlike this, the substrate processing apparatus may be an apparatus for applying an antireflection film, a protective film, or another kind of liquid onto a substrate.

FIG. 2 is a diagram schematically illustrating a substrate processing apparatus according to an exemplary embodiment of the present invention. Referring to FIG. 2, a substrate processing apparatus 1 includes a liquid treating chamber 10, a liquid supply unit 20, and a controller 30. The liquid treating chamber 10 applies a photoresist film to the substrate W loaded therein. The liquid supply unit 20 supplies a photoresist to the liquid treating chamber 10. The controller 30 controls the liquid treating chamber 10 and the liquid supply unit 20.

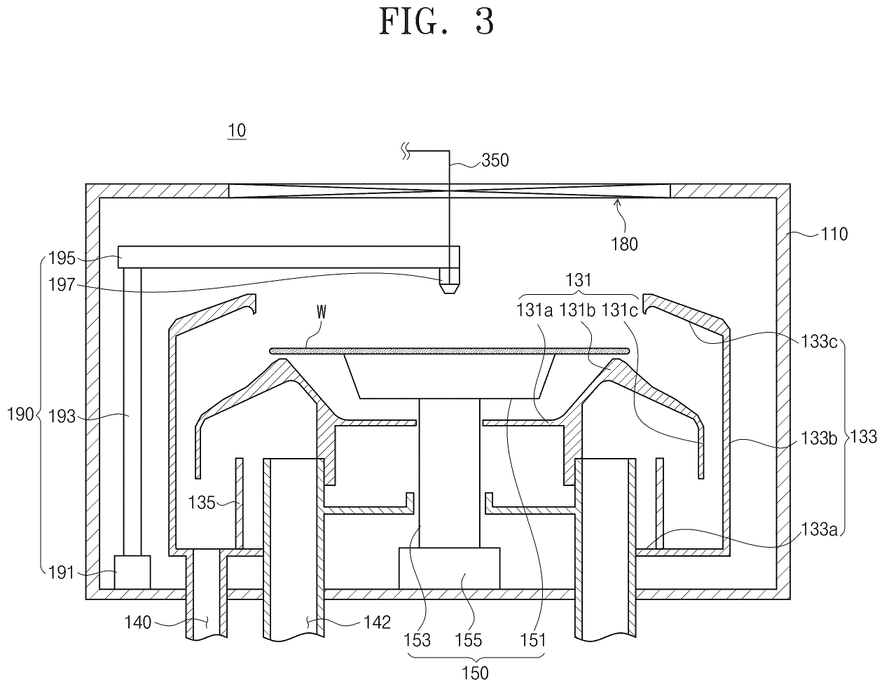

FIG. 3 is a diagram schematically illustrating an example of the liquid treating chamber of FIG. 2. Referring to FIG. 2, the liquid treating chamber 10 may include a housing 110, a cup 133, a support unit 150, a guide ring 131, an airflow supply unit 180, and a nozzle unit 190.

The housing 110 provides space therein. The housing 110 is provided in a generally rectangular parallelepiped shape. An opening (not illustrated) is formed at one side of the housing 110. The opening (not illustrated) functions as an entrance through which the substrate W is loaded into the interior space or the substrate W is unloaded from the interior space. Also, a door (not illustrated) is installed in an area adjacent to the entrance to selectively open and close the entrance. A door (not illustrated) blocks the entrance and seals the interior space from the outside while the processing process is performed on the substrate W loaded into the interior space.

The cup 133, the support unit 150, the guide ring 131, and the nozzle unit 190 may be disposed in the interior space of the housing 110.

The cup 133 may be provided to surround the support unit 150 and the guide ring 131. The cup 133 may include a bottom wall 133a, a side wall 133b, and an upper wall 133c.

The bottom wall 133a may have a circular plate shape having a hollow. A discharge pipe 140 is connected to the bottom wall 133a. After processing the substrate W, the liquid scattered from the substrate W is discharged to the outside of the cup 133 through the discharge pipe 140.

An exhaust pipe 142 is connected to the bottom wall 133a. The exhaust pipe 142 is connected to the bottom wall 133a from the inner side than the exhaust pipe 140. Fume and airflow flowing in the cup 133 are exhausted to the outside of the cup 133 through the exhaust pipe.

The gas-liquid separation plate 135 may be installed on the bottom wall 133a. The gas-liquid separation plate 135 may be provided in an annular shape. The gas-liquid separation plate 135 is installed between the discharge pipe 140 and the exhaust pipe 142. The gas-liquid separation plate 135 prevents liquids used for processing the substrate W from flowing into the exhaust pipe 142.

The sidewall 133b may be provided in an annular ring shape surrounding the guide ring 131. The sidewall 133b may extend in a vertical direction from a side end of the bottom wall 133a.

The upper wall 133c may extend in a direction from an upper end of the side wall 133b toward a central axis of the outer cup 133. An inner surface of the upper wall 133c may extend to be inclined upward with respect to the ground as it approaches a central axis of the outer cup 133. The upper wall 133c may be provided to have a ring shape when viewed from above. While the processing of the substrate W is performed, the upper end of the upper wall 133c may be positioned to be higher than the upper surface of the substrate W supported by the support unit 150.

The support unit 150 supports and rotates the substrate W in a processing space. The support unit 150 may be a spin chuck that supports and rotates the substrate W. The support unit 150 may include a body 151, a support shaft 153, and a driving unit 155.

The guide ring 131 may have an inner wall 131a, an upper wall 131b, and an outer wall 131c. The inner wall 131a, the upper wall 131b, and the outer wall 131c may be combined with each other to provide a space in which the lower portion is open. The support shaft 153 of the support unit 150 may be surrounded by the inner wall 131a. The outer wall 131c may be combined with the cup 133 to form a discharge path through which the processing medium is discharged. The upper wall 131b may be provided to be inclined upward toward the outside from the inner wall 131a, and may then have a shape inclined downward toward the outer wall 131c.

The body 151 may have a top surface on which the substrate W is seated. The top surface of the body 151 may be provided in an approximately circular shape when viewed from the top. The top surface of the body 151 may have a diameter smaller than that of the substrate W. An adsorption hole (not illustrated) may be formed in the body 151. The adsorption hole (not illustrated) may vacuum-adsorb the substrate W seated on the top surface of the body 151.

The support shaft 153 is coupled with the body 151. The support shaft 153 may be coupled to a lower surface of the body 151. The longitudinal direction of the support shaft 153 may be provided in a vertical direction. The driving unit 155 may provide power for rotating the support shaft 153 with respect to a central axis thereof and for moving the support shaft 153 in a vertical direction. Accordingly, a relative height between the support unit 150 and the cup 133 may be adjusted.

An airflow supply unit 180 is installed on an upper end of the housing 110. The airflow supply unit 180 may supply airflow having a temperature and/or humidity adjusted to the interior space. The airflow supply unit 180 may be a Fan Filter Unit (FFU).

The nozzle unit 190 is provided in the housing 110. The nozzle unit 190 receives a liquid from the liquid supply unit 20 and supplies the liquid to the substrate W supported by the support unit 150. The nozzle unit 190 may include a driver 191, a support rod 193, an arm 195, and a nozzle 197.

The support rod 193 is located in the interior space of the housing 110. The support rod 193 is located on one side of a processing container 420 in the interior space. The support rod 193 may have a rod shape whose longitudinal direction faces a vertical direction.

The arm 195 is coupled to an upper end of the support rod 193. The arm 195 extends vertically from the longitudinal direction of the support rod 193. The nozzle 197 to be described later may be fixedly coupled to the end of the arm 195.

The driver 191 is coupled with the support rod 193. The driver 191 may be disposed on the bottom surface of the housing 110. The driver 191 provides driving force for rotating the support rod 193. The driver 191 may be provided as a motor.

The liquid supply unit 20 supplies a photoresist to the nozzle 197 provided in the liquid treating chamber 10.

Referring to FIG. 2, the liquid supply unit 20 includes a bottle 200, a supply pipe 300, a pump 400, a trap tank 500, a liquid delivering unit 600, and a gas supply unit 2000.

The bottle 200 has a storage space for storing photoresists. A plurality of bottles 200 may be provided. For example, the bottle 200 may include a first bottle 200a and a second bottle 200b. Accordingly, first, a photoresist is supplied from the first bottle 200a to the trap tank 500. When the photoresist is exhausted from the first bottle 200a, the photoresist is supplied from the second bottle 200b to the trap tank 500. While the photoresist is supplied from the second bottle 200b, the first bottle 200a from which the photoresist is exhausted is replaced with a new bottle 200 filled with the photoresist. The first bottle 200a and the second bottle 200b have the same or similar structures.

The supply pipe 300 supplies the photoresist in the bottle 200 to the liquid treating chamber 10. The supply pipe 300 is provided with a flow path through which the photoresist may flow. The trap tank 500 and the pump 400 are installed in the supply pipe 300. The trap tank 500 and the pump 400 are sequentially disposed in a direction from the upstream to the downstream. The supply pipe 300 has a first pipe 310, a second pipe 330, and a third pipe 350. The first pipe 310 connects the bottle 200 and the trap tank 500. The second pipe 330 connects the trap tank 500 and the pump 400. The third pipe 350 connects the pump 400 and the nozzle 197.

Opening and closing valves 310a, 330a, and 350a for opening and closing the flow path are installed in the first to third pipes 310, 330, and 350, respectively.

The photoresist stored in the bottle 200 is supplied to the trap tank 500. The trap tank 500 has an interior space for temporarily storing photoresists. Water level detection sensors 510 and 530 are installed in the trap tank 500. The water level detection sensors 510 and 530 detect the water level of the photoresist stored in the interior space of the trap tank 500. A plurality of water level detection sensors 510 and 530 may be provided. When the water level is detected by the water level detection sensors 510 and 530, the controller 30 may transmit information on the amount of photoresist remaining in the trap tank 500 to the user.

The pump 400 provides a flow pressure for flowing a photoresist temporarily stored in the trap tank 500 into the liquid treating chamber 10.

The liquid delivering unit 600 provides power for delivering the photoresist in the bottle 200 to the trap tank 500. According to the example, the liquid delivering unit 600 may be connected to the trap tank 500 to form negative pressure in the interior space of the trap tank 500. Selectively, the liquid delivering unit 600 may include an ejector 610. Hereinafter, a case in which the liquid delivering unit 600 includes the ejector 610 will be described.

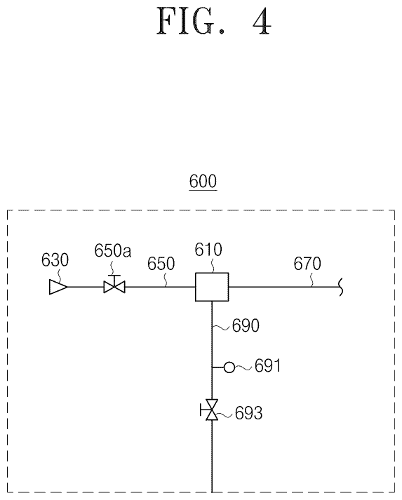

Referring to FIG. 4, the liquid delivering unit 600 includes an ejector 610, a gas supply source 630, an inlet pipe 650, an outlet pipe 670, and a suction pipe 690.

The inlet pipe 650 and the outlet pipe 670 are connected to both ends of the ejector 610, respectively, and the suction pipe 690 is connected to a lower end thereof. The gas supplied from the gas supply source 630 flows into the ejector 610 through the inlet pipe 650 and is discharged to the outside through the outlet pipe 670, thereby forming negative pressure in the interior space of the trap tank 500 connected to the suction pipe 690.

The suction pipe 690 is provided with a sensor 691 and a valve 693. The sensor 691 detects whether a photoresist is introduced into the suction pipe 690. According to the example, the sensor 691 may be an optical sensor. The valve 693 may be an on/off valve that opens and closes an internal flow path of the suction pipe 690.

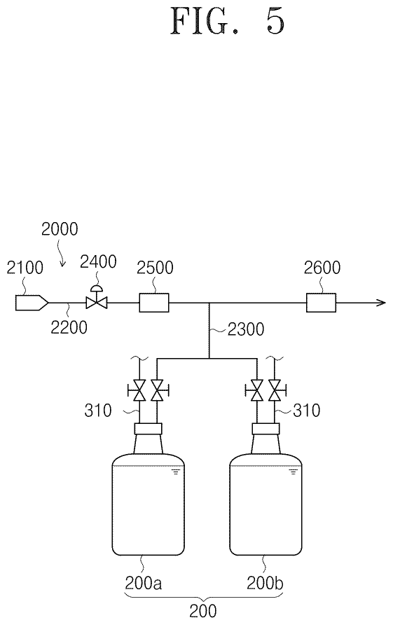

FIG. 5 is a diagram schematically illustrating one example of the gas supply unit of FIG. 2. Referring to FIG. 5, the gas supply unit 2000 may include a gas supply source 2100, a main pipe 2200, a branch pipe 2300, a regulator 2400, a first resistor 2500, and a second resistor 2600.

When the stored photoresist of the bottle 200 is delivered to the trap tank 500, the gas supply unit 2000 may fill the empty space inside the bottle 200 with gas by a reduced pressure in the storage space of the bottle 200. Accordingly, the pressure in the storage space of the bottle 200 before and after the delivery of the photoresist becomes the same, it is possible to prevent the external atmosphere from flowing into the bottle 200, and the internal pressure is maintained to prevent deformation of the bottle 200.

Gas is stored in the gas supply source 2100. The gas may be inert gas. According to the example, the gas may be nitrogen gas (N₂).

The main pipe 2200 receives gas from the gas supply source 2100 and exhausts the gas to the outside. One end of the main pipe is connected to a gas supply source, and the other end of the main pipe is open to the atmosphere. The main pipe 2200 is provided with the regulator 2400, the first resistor 2500, and the second resistor 2600. The regulator 2400, the first resistor 2500, and the second resistor 2600 are sequentially disposed in a direction from the upstream to the downstream.

Since the other end of the main pipe 2200 is open to the atmosphere, the internal pressure of the main pipe 2200 decreases toward the downstream from the upstream.

The regulator 2400 depressurizes the gas pressure of the gas supplied from the gas supply source to a set pressure. According to the example, the regulator 2400 depressurizes tens of kPa of gas supplied from the gas supply source 2100 to several kPa.

The first resistor 2500 provides resistance to the flow of gas and reduces the gas pressure of the gas that has passed through the regulator. According to the example, the first resistor 2500 may be a flow control valve.

The branch pipe 2300 is branched from the main pipe 2200 and supplies gas to the storage space of the bottle 200. The branch pipe 2300 is branched from the main pipe 2200 at a position between the first resistor 2500 and the second resistor 2600. Since the pressure in the storage space of the bottle 200 is the same as the internal pressure in the main pipe 2200 at the branch point where the branch pipe 2300 is branched from the main pipe 2200, the pressure in the storage space of the bottle 200 is determined by the position of the branch point. According to the example, the position of the branch point may be determined such that the gauge pressure in the storage space of the bottle 200 is maintained at several Pa. Selectively, the position of the branch point may be determined such that the gauge pressure in the storage space of the bottle 200 is maintained at 0 Pa or more and 6 Pa or less.

Since the gas pressure in the storage space of the bottle 200 is only a few Pa, a large amount of gas is prevented from being dissolved in the photoresist delivered from the bottle 200. Accordingly, it is possible to prevent a large amount of air bubbles from being generated in the photoresist when the photoresist moves through the supply pipe 300.

The second resistor 2600 provides resistance to the flow of the gas and adjusts the amount of exhaust gas exhausted to the outside.” The second resistor 2600 reduces the amount of unnecessarily exhausted gas. According to the example, the second resistor 2600 may be a flow control valve.

The controller 30 controls the substrate processing apparatus 1 to perform a substrate processing method described below.

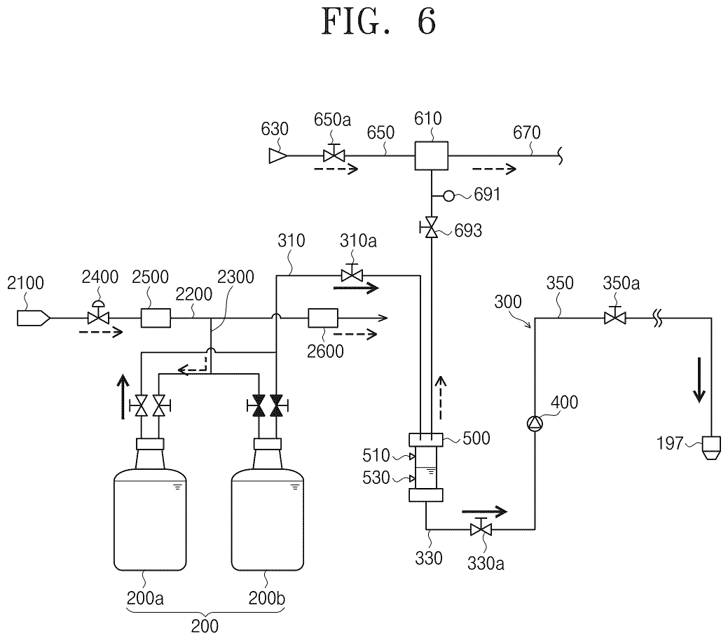

FIGS. 6 to 9 are diagrams schematically illustrating an exemplary embodiment of a process of supplying a liquid in the substrate processing apparatus of FIG. 2. In FIGS. 6 to 9, the valve filled with the inside is a closed state for preventing the fluid from flowing, and the valve empty with the inside is an open state for allowing the fluid to flow. An arrow indicated by a solid line means the flow direction of the photoresist, and an arrow indicated by a dotted line means the flow direction of the gas. In addition, the sensor 691 filled with the inside means a state in which the flow of the photoresist is detected, and the sensor 691 with the inside empty means a state in which the flow of the photoresist is not detected.

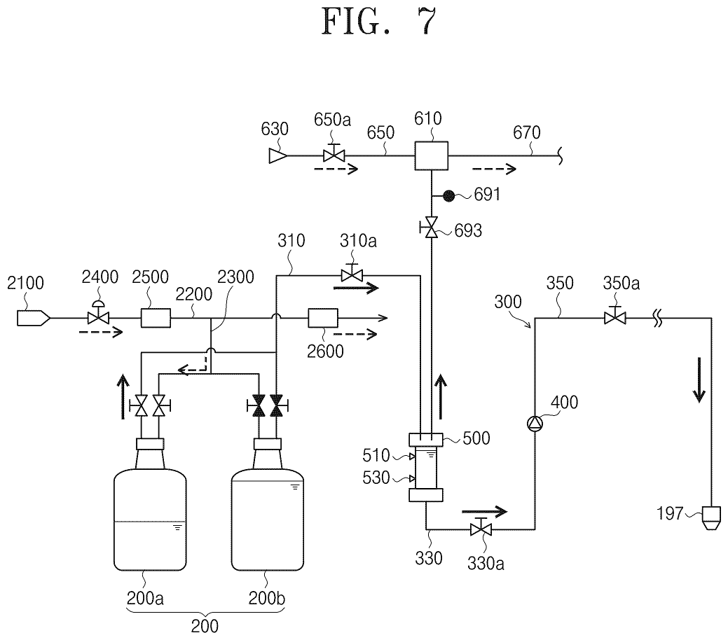

FIGS. 6 and 7 are diagrams schematically illustrating one exemplary embodiment of a process in which the liquid delivering unit operates to transfer a liquid in the substrate processing apparatus of FIG. 2.

Referring to FIG. 6, the liquid delivering unit 600 flows gas to the ejector 610 to form a negative pressure in the interior space of the trap tank 500. Accordingly, the photoresist in the storage space of the bottle 200 is delivered to the trap tank 500. The gas supplied from the gas supply source 2100 is supplied to the storage space of the bottle 200 as much as the decreased pressure in the storage space of the bottle 200 generated when the photoresist is delivered to the trap tank 500.

The controller 30 may operate the pump 400 to supply the photoresist in the trap tank 500 to the nozzle 197 in order to supply the photoresist to the substrate as needed.

When the photoresist supplied from the bottle 200 is filled in the interior space of the trap tank 500 at a predetermined level or more, a part of the photoresist delivered into the trap tank 500 flows into the suction pipe 690 as illustrated in FIG. 7. The photoresist introduced into the suction pipe 690 is detected by the sensor 691, and the detection result is transmitted to the controller 30. The controller 30 receives a detection signal from the sensor 691 and closes the valve 693 installed in the suction pipe 690.

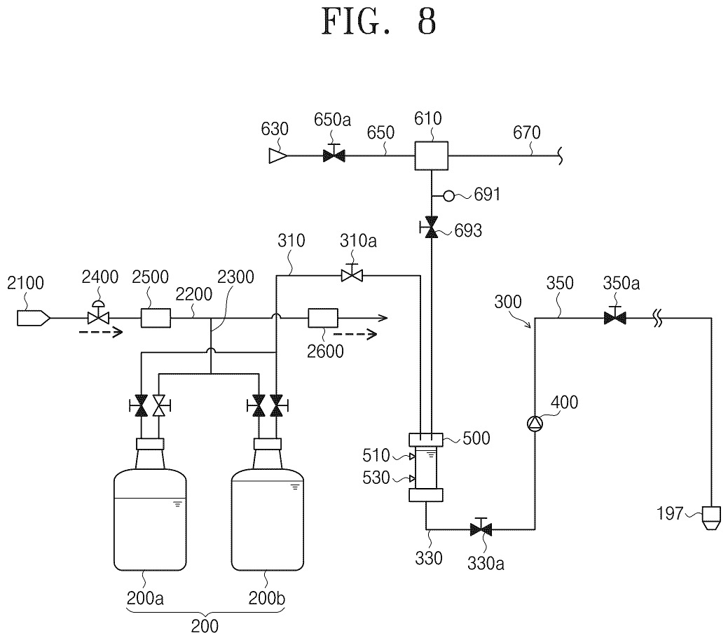

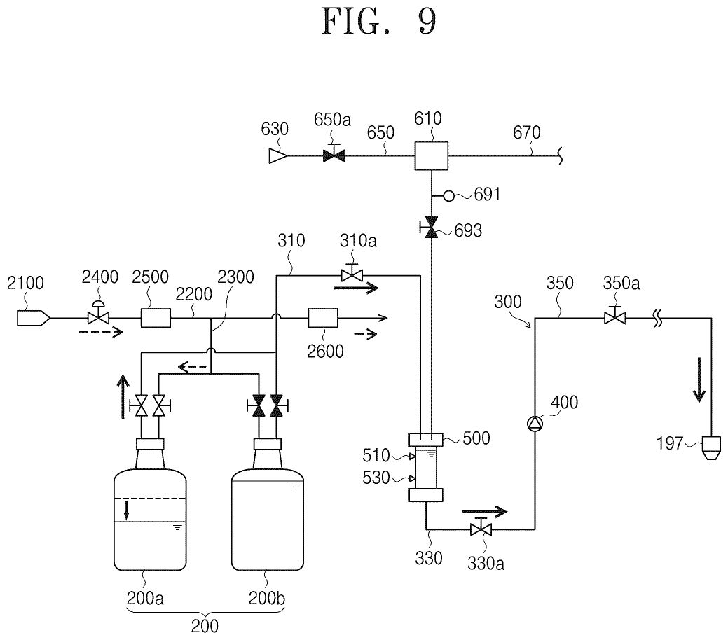

FIG. 8 is a diagram schematically illustrating one exemplary embodiment of the substrate processing apparatus of FIG. 2 in a state where a pump does not operate after the valve installed in the suction pipe has been closed, and FIG. 9 is a diagram schematically illustrating one exemplary embodiment of a process of liquid transfer in the substrate processing apparatus of FIG. 2 in a state where the pump operates after the valve installed in the suction pipe has been closed. The length of the arrow illustrated by the dotted line in FIG. 8 and FIG. 9 schematically illustrates the relative flow rate of gas at each location.

Referring to FIG. 8, since the pump 400 does not operate, the photoresist in the storage space of the bottle 200 is not transferred to the trap tank 500. Since the pressure in the storage space of the bottle 200 is the same as the internal pressure of the main pipe 2200 at the branch point, the inside of the branch pipe 2300 is in a dynamic equilibrium state. Accordingly, the gas passing through the first resistor 2500 is exhausted to the outside through the branch point and the second resistor 2600.

Referring to FIG. 9, since no negative pressure is formed in the interior space of the trap tank 500, the photoresist in the trap tank 500 is delivered to the nozzle 197 by the flow pressure of the pump 400, and the photoresist is delivered from the bottle 200 to the trap tank 500 as much as the amount delivered from the trap tank 500 to the nozzle 197.

When the photoresist is delivered from the bottle 200 to the trap tank 500, a difference between the internal pressure of the main pipe 2200 at a branch point and the pressure in the storage space of the bottle 200 is temporarily generated, and a part of the gas that has passed through the first resistor 2500 is filled in the storage space of the bottle 200 through the branch pipe 2300. Accordingly, the internal pressure of the main pipe 2200 at the branch point and the pressure in the storage space of the bottle 200 become the same, and the exhaust amount of gas exhausted to the outside through the second resistor 2600 is reduced.

Since the internal pressure of the main pipe 2200 at the branch point is constant regardless of whether or not the photoresist is delivered, the pressure in the storage space of the bottle 200 is the same before and after the photoresist is delivered.

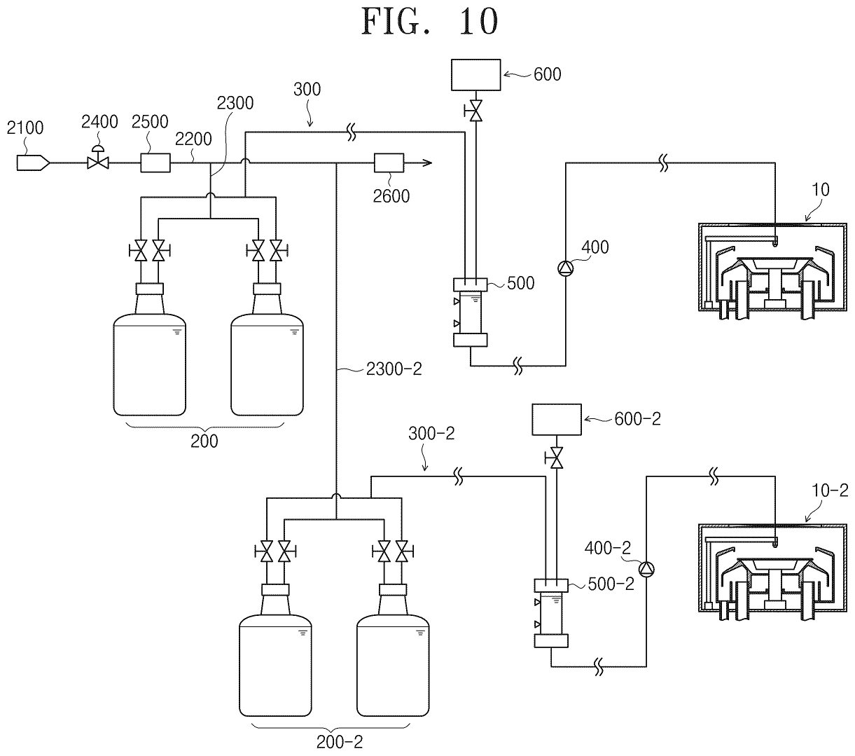

In the exemplary embodiment of FIG. 2 described above, a case where one liquid supply unit 20 and one liquid treating chamber 10 are provided has been described as an example. However, the present invention is not limited thereto, and as illustrated in FIG. 10, the substrate processing apparatus may further include a second liquid treating chamber 10-2 for treating a second substrate and a second liquid supply unit 20-2 for supplying a second liquid to the second substrate disposed in the second liquid treating chamber. The second liquid supply unit 20-2 may include a second bottle 200-2, a second supply pipe 300-2, a second trap tank 500-2, a second liquid delivering unit 600-2, a second pump 400-2, and a second branch pipe 2300-2. The second branch pipe 2300-2 may be branched from the main pipe 2200 downstream from the branch pipe 2300 and connected to the second bottle 200-2. The second liquid treating chamber 10-2 may have the same or similar structure as or to the liquid treating chamber 10. The second liquid may be a photoresist. However, unlike this, the second liquid may be a chemical liquid required to perform a separate process. The second substrate may be a component that performs the same function as the substrate. However, unlike this, it may be a component that performs a separate function from the substrate.

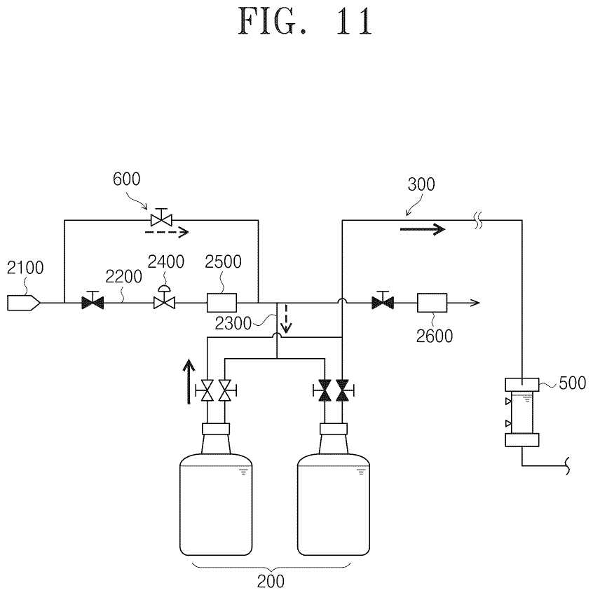

In the above-described exemplary embodiment of FIG. 4, a case in which the liquid delivering unit 600 forms negative pressure in the interior space of the trap tank 500 through the ejector 610 has been described as an example. However, the present invention is not limited thereto, and as illustrated in FIG. 11, the high-pressure gas supplied from the gas supply source 2100 may be supplied to the storage space of the bottle 200 to deliver the photoresist in the bottle 200 to the trap tank 500.

In the above-described exemplary embodiment of FIG. 2, a case in which a plurality of bottles 200 is provided has been described as an example. However, the present invention is not limited thereto, and one bottle 200 may be provided to store liquid.

In the exemplary embodiment of FIG. 2 described above, a case where the second resistor 2600 is provided has been described as an example. However, unlike this, the second resistor 2600 may not be provided to the main pipe 2200.

In the exemplary embodiment of FIG. 2 described above, a case where the first resistor 2500 and the second resistor 2600 are flow control valves has been described as an example. However, the present invention is not limited thereto, and the first resistor 2500 or the second resistor 2600 may be an orifice. Alternatively, the main pipe 2200 may not be provided with the first resistor 2500 and the second resistor 2600, and the main pipe 2200 may be provided as a long and narrow pipe.

In the above-described exemplary embodiment of FIG. 7, it has been described that when a photoresist is detected by the sensor 691, the valve 693 installed in the suction pipe 690 is closed. However, the present invention is not limited thereto, and when a photoresist is detected by the water level sensor 510 provided at the upper end side of the trap tank 500, the valve 693 installed in the suction pipe 690 may be controlled to be closed.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. An apparatus for processing a substrate, the apparatus comprising:
a liquid treating chamber for processing a substrate; and
a liquid supply unit for supplying a liquid to the substrate disposed in the liquid treating chamber,
wherein the liquid supply unit includes:
a bottle in which a storage space for storing a liquid is formed;
a supply pipe for providing a path through which the liquid in the bottle flows to the liquid treating chamber;
a trap tank installed in the supply pipe and having an interior space where the liquid delivered from the bottle is stored;
a pump installed downstream of the trap tank in the supply pipe and providing flow pressure to the fluid flowing in the supply pipe; and
a gas supply unit for supplying gas to the storage space, and
the gas supply unit includes:
a main pipe for receiving the gas from the gas supply source and exhausting the received gas to the outside;
a branch pipe branched from the main pipe and connected to the storage space of the bottle; and
a regulator installed upstream from a branch point where the branch pipe is branched from the main pipe in the main pipe to reduce pressure of the gas supplied from the gas supply source.

2. The apparatus of claim 1, wherein the gas supply unit further includes a resistor that is installed in the main pipe downstream from the regulator to reduce the pressure of the gas.

3. The apparatus of claim 2, wherein the resistor is installed between the regulator and the branch point.

4. The apparatus of claim 2, wherein the resistor is a flow control valve.

5. The apparatus of claim 2, wherein the resistor is an orifice.

6. The apparatus of claim 1, wherein the gas supply unit further includes:
a first resistor installed in the main pipe downstream from the regulator and reducing the pressure of the gas; and
a second resistor installed in the main pipe downstream from the first resistor to reduce an exhaust amount of the gas.

7. The apparatus of claim 1, wherein the gas is inert gas.

8. The apparatus of claim 1, wherein the branch point is a position where a gauge pressure in the storage space is maintained at several Pa.

9. The apparatus of claim 1, wherein the liquid supply unit further includes a liquid delivering unit that delivers a liquid from the bottle to the trap tank.

10. The apparatus of claim 9, wherein the liquid delivering unit forms negative pressure in the interior space of the trap tank to deliver the liquid from the bottle to the trap tank.

11. The apparatus of claim 1, further comprising:
a second liquid treating chamber for processing a second substrate; and
a second liquid supply unit for supplying a second liquid to the second substrate disposed in the second liquid treating chamber,
wherein the second liquid supply unit includes:
a second bottle in which a second storage space for storing the second liquid is formed;
a second supply pipe for providing a path through which the second liquid in the second bottle flows to the second liquid treating chamber;
a second trap tank installed in the second supply pipe and having an interior space in which the second liquid delivered from the second bottle is stored;
a second liquid delivering unit for delivering a liquid from the second bottle to the second trap tank;
a second pump installed downstream of the second trap tank in the second supply pipe and providing flow pressure to the second liquid flowing in the second supply pipe; and
a second branch pipe for receiving gas from the gas supply source, and
the second branch pipe is branched from the main pipe downstream from the branch pipe and connected to the storage space of the bottle.

12-17. (canceled)

18. An apparatus for processing a substrate, the apparatus comprising:
a liquid treating chamber for processing a substrate; and
a liquid supply unit for supplying a liquid to the substrate disposed in the liquid treating chamber,
wherein the liquid supply unit includes:
a bottle in which a storage space for storing a liquid is formed;
a supply pipe for providing a path through which the liquid in the bottle flows to the liquid treating chamber;
a trap tank installed in the supply pipe and having an interior space where the liquid delivered from the bottle is stored;
a liquid delivering unit for delivering a liquid from the bottle to the trap tank;
a pump installed downstream of the trap tank in the supply pipe and providing flow pressure to the fluid flowing in the supply pipe; and
a gas supply unit for supplying inert gas to the storage space, and
the gas supply unit includes:
a main pipe for receiving the inert gas from the gas supply source and exhausting the received inert gas to the outside;
a branch pipe branched from the main pipe and connected to the storage space of the bottle;
a regulator installed upstream from a branch point where the branch pipe is branched from the main pipe in the main pipe to reduce pressure of the inert gas supplied from the gas supply source;
a first flow control valve installed in the main pipe between the regulator and the branch point to reduce the pressure of the inert gas; and
a second flow control valve installed in the main pipe downstream from the branch point to reduce the exhaust amount of the inert gas.

19. The apparatus of claim 18, wherein the branch point is a position where a gauge pressure in the storage space is maintained at several Pa.

20. The apparatus of claim 18, further comprising:
a second liquid treating chamber for processing a second substrate; and
a second liquid supply unit for supplying a second liquid to the second substrate disposed in the second liquid treating chamber,
wherein the second liquid supply unit includes:
a second bottle in which a second storage space for storing the second liquid is formed; a second supply pipe for providing a path through which the second liquid in the second bottle flows to the second liquid treating chamber;
a second trap tank installed in the second supply pipe and having an interior space in which the second liquid delivered from the second bottle is stored;
a second liquid delivering unit for delivering the second liquid from the second bottle to the second trap tank;
a second pump installed downstream of the second trap tank in the second supply pipe and providing flow pressure to the second liquid flowing in the second supply pipe; and
a second branch pipe for receiving gas from the gas supply source, and
the second branch pipe is installed in the main pipe between the branch point and the second flow control valve and connected to the second storage space of the second bottle.
